(19) United States
(12) Patent Application Publication
(10) Pub. No.: US 2024/0363394 A1
(43) Pub. Date: Oct. 31, 2024

(54) INTEGRATED CIRCUIT WITH IMPROVED ISOLATION

(71) Applicant: TEXAS INSTRUMENTS INCORPORATED, Dallas, TX (US)

(72) Inventors: Dong Seup Lee, McKinney, TX (US); Sunglyong Kim, Dallas, TX (US); Meng-Chia Lee, Dallas, TX (US); Satoshi Suzuki, Miho (JP); Seetharaman Sridhar, Richardson, TX (US)

(21) Appl. No.: 18/141,153

(22) Filed: Apr. 28, 2023

(51) Int. Cl. H01L 21/761; H01L 27/088

(52) U.S. Cl. CPC H01L 21/761; H01L 27/088; H01L 21/2652; H01L 21/266; H01L 29/66681

(57) ABSTRACT

Described examples include an integrated circuit having a substrate, a first doped region in the substrate having a first conductivity type, and a first epitaxial layer on the substrate, wherein the first doped region extends into the first epitaxial layer. The integrated circuit also has a second doped region in the first epitaxial layer having the first conductivity type, a second epitaxial layer on the first epitaxial layer, wherein the second doped region extends into the second epitaxial layer. The integrated circuit also has a well in the second epitaxial layer having a second conductivity type, and a first active device formed in the well.

### TECHNICAL FIELD

This relates generally to integrated circuits and their manufacture, and more particularly, but not exclusively, to improved breakdown voltage of transistors used in voltage conversion implementations.

### BACKGROUND

High voltage semiconductor devices use one or more of several techniques to both contain and distribute high fields to allow the semiconductor to operate with high voltages. Structures such as laterally diffused metal-oxide semiconductor (LDMOS) transistors allow for operation of 700 V or more for the breakdown voltage from the drain to source (BVdss). Such devices may also suffer from breakdown between the source of an LDMOS transistor formed in a well and the isolation structure that isolates that transistor from other devices in the same substrate (BViso). In some circuits, an increase in this breakdown voltage is needed. This breakdown voltage depends on two buried layers of opposite conductivity that are adjacent to each other that are heavily doped. This provides a relatively thin PN junction barrier layer between the two buried layers. This barrier layer can be increased by lowering the doping of one or both of the buried layers. However, the doping of these layers cannot be changed without adversely affecting BVdss. It is desirable to increase the isolation breakdown voltage without adversely affecting other breakdown voltages.

### SUMMARY

In accordance with an example, an integrated circuit includes a first epitaxial layer having a first conductivity type over a semiconductor substrate having a top surface. A second epitaxial layer having the first conductivity type is located over the first epitaxial layer. A first doped region having a different second conductivity type is located between the substrate and the first epitaxial layer. A second doped region having the first conductivity type is located between the first epitaxial layer and the second epitaxial layer. A well region having the first conductivity type extends from the top surface into the second epitaxial layer over the first doped region. An active device is located over the first doped region in the well.

### BRIEF DESCRIPTION OF THE DRAWINGS

FIG. 1 is a schematic diagram of an example circuit.

FIG. 2 is a cross-sectional view of an example integrated circuit.

FIG. 3 is a cross-sectional view of an example integrated circuit.

FIGS. 4A-4O (collectively “FIG. 4”) are sectional views illustrating an example method of fabricating an example integrated circuit.

FIGS. 5A-5O (collectively “FIG. 5”) are sectional views illustrating another example method of fabricating another example integrated circuit.

FIG. 6 is a cross-sectional view of an example integrated circuit.

### DETAILED DESCRIPTION

In the drawings, corresponding numerals and symbols generally refer to corresponding parts unless otherwise indicated. The drawings are not necessarily drawn to scale.

In this description, the term “coupled” may include connections made with intervening elements, and additional elements and various connections may exist between any elements that are “coupled.” Also, as used herein, the terms “on” and “over” may include layers or other elements where intervening or additional elements are between an element and the element that it is “on” or “over.”

Various disclosed methods and devices of the present disclosure may be beneficially applied to transistors, e.g., LDMOS transistors, used in switching DC-DC converters and other applications to increase voltage breakdown characteristics, while allowing integration of such transistors on a same substrate with similar transistors with lower breakdown voltage characteristics. While such examples may be expected to provide flexible integration of devices with different voltage breakdown characteristics, no particular result is a requirement of the present invention unless explicitly recited in a particular claim.

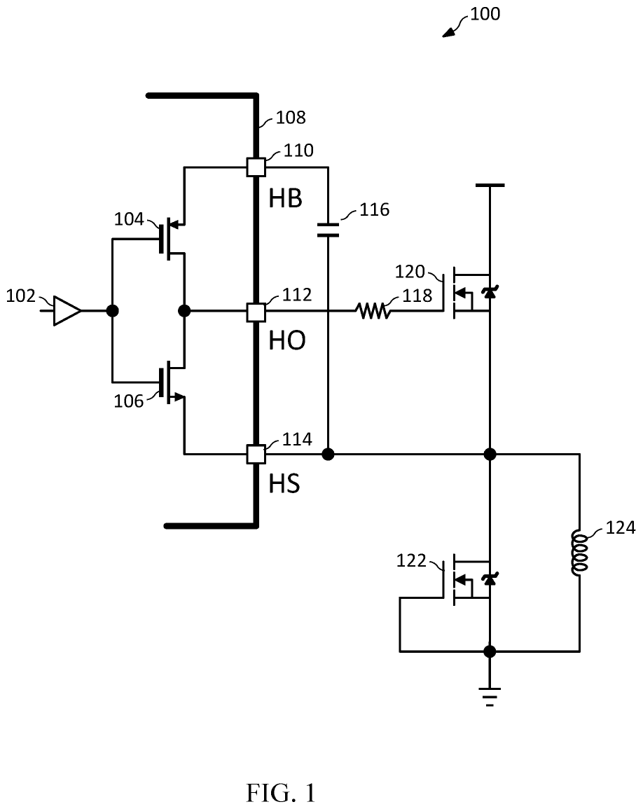

FIG. 1 is a schematic diagram of an example circuit 100, e.g., a buck voltage converter. Buffer 102 drives the gates of p-channel high-side LDMOS transistor 104 and n-channel low-side LDMOS transistor 106. These components are on integrated circuit 108. The source of transistor 104 is coupled to HB node 110. The drains of both transistor 104 and transistor 106 are coupled to HO node 112. The source of transistor 106 is coupled to HS node 114. In some examples the nodes 110, 112 and 114 are package pins. Capacitor 116 is coupled between the HB node 110 and the HS node 114 to smooth voltage spikes. Resistor 118 is coupled between the HO node 112 and the gate of driver transistor 120. Resistor 118 cooperates with the capacitance of the gate of driver transistor 120 to provide a delay to allow the output of transistor 120 to ramp smoothly. When the HO node 112 is high, transistor 120 is “on” and current is applied to inductor 124 to store energy. When the HO node 112 is low, transistor 120 is “off” and energy is released by inductor 124. Transistor 122 is diode-connected and configured to dissipate reverse voltage spikes that may occur across inductor 124. In spite of the features of circuit 100 to avoid voltage spikes, such events can occur between the HB node 110 and the HS node 114. For example, when 106 is “on,” HO node 112 is connected to the HS node 114. This turns transistor 120 “off” and voltage at the HS node 114 drops as the inductor 124 voltage decays. Due to ringing, the voltage at the HS node 114 can go below the low-voltage reference, e.g., zero volts (ground). This behavior may result in decreased reliability or lifetime of circuit 100.

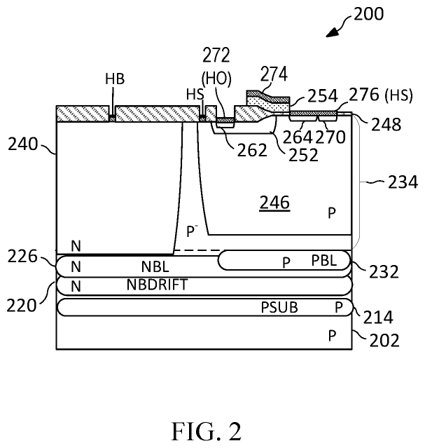

FIG. 2 is a cross-sectional view of an example baseline integrated circuit 200 that may implement the transistor 104 and the transistor 106. The integrated circuit 200 may be representative of some baseline implementations. A transistor device 201 is located over a P-type substrate 202 in this example. PSUB region 214, NDRIFT region 220, N buried layer (NBL) 226, and P buried layer (PBL) 232 are located over substrate 202. Lightly doped P type epitaxial layer 234 is located over NBL 226 and PBL 232. N isolation region 240 may electrically isolate device 201 from other devices located over the same substrate 202. Of note, NBL 226 and isolation region 240 are in contact, and thus are electrically conductive between each other. P well 246 within epitaxial layer 234 is located over PBL 232. Transistor device 201 includes extended drain 252, contact 262, drain silicide layer 272, source 264, well or body contact 270, and source silicide layer 276 located in P well 246. Gate 254 and silicide layer 274 located over gate oxide layer 248 provide a control node of the transistor device 201 (e.g., a common gate of the transistors 104 and 106 of FIG. 1). An HB node and an HS node respectively correspond to HB node 110 and HS node 114 described in FIG. 1. NBL 226 is connected to the HB node by way of N isolation region 240, and PBL 232 is connected to the HS node by way of the epitaxial layer 234 and P well 246. As described previously, the voltage at the HS node may experience low-voltage excursions, which increases the voltage drop between the HB node and the HS node. The larger voltage increases the voltage across the depletion region formed between the NBL 226 and the PBL 232. Because NBL 226 and the PBL 232 have a relatively high doping level, the depletion region may be narrow, resulting in an electric field that exceeds the breakdown voltage of the silicon substrate, leading to breakdown, or “punch-through”.

In an example, the breakdown voltage between HB and HS may be about 20 V. If a breakdown occurs, a short between HB and HS will be formed and integrated circuit 108 may be rendered inoperable. While the breakdown voltage can be increased by lowering the doping of either NBL 226 or PBL 232, thus increasing the width of the depletion region, such a change of doping could reduce the drain-to-source breakdown voltage of transistor 206 in some cases. In addition, in many integrated circuits, other devices on the same substrate typically utilize an NBL and/or PBL formed by same process conditions that form the NBL 226 and PBL 232. The operating characteristics of such other devices could therefore be undesirably changed by altering the doping of NBL 226 and/or PBL 232.

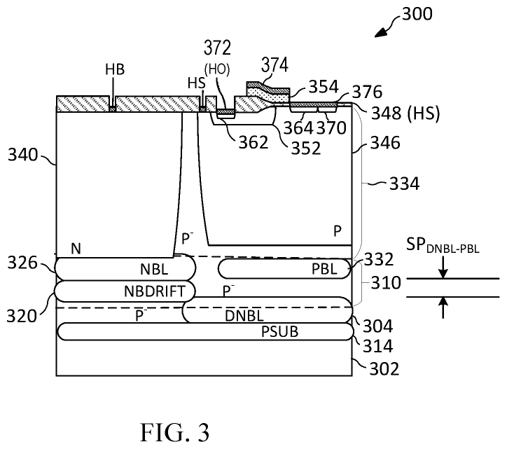

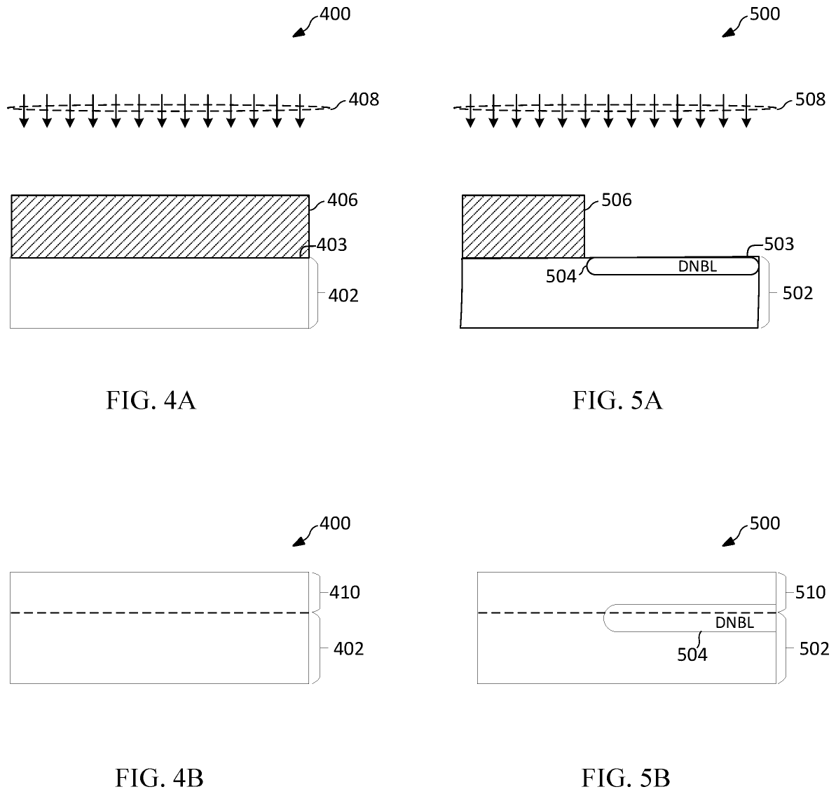

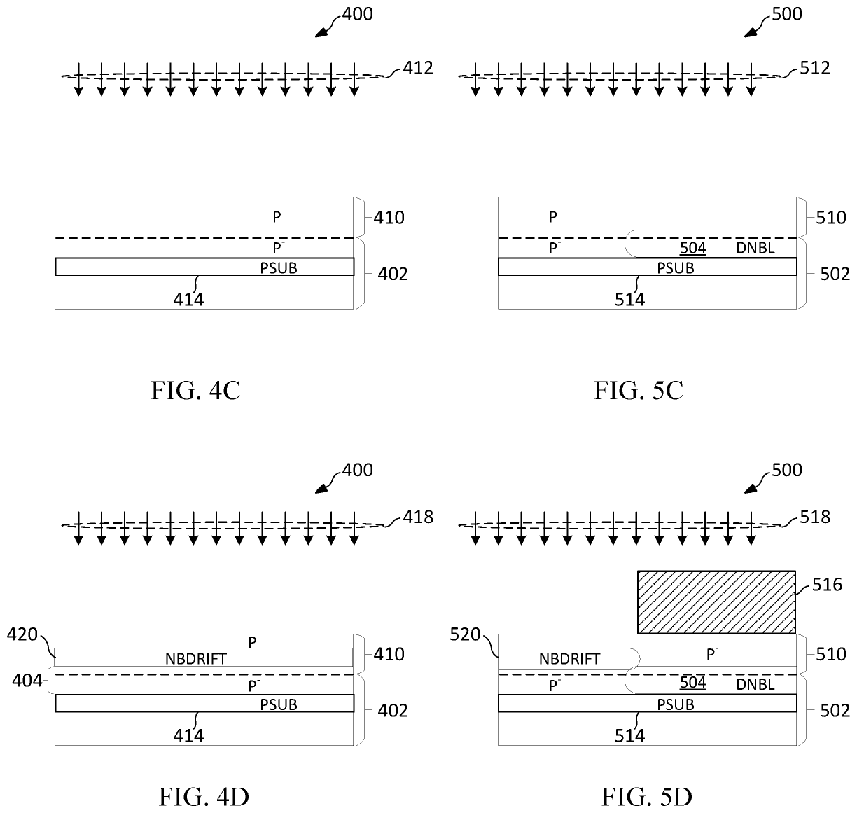

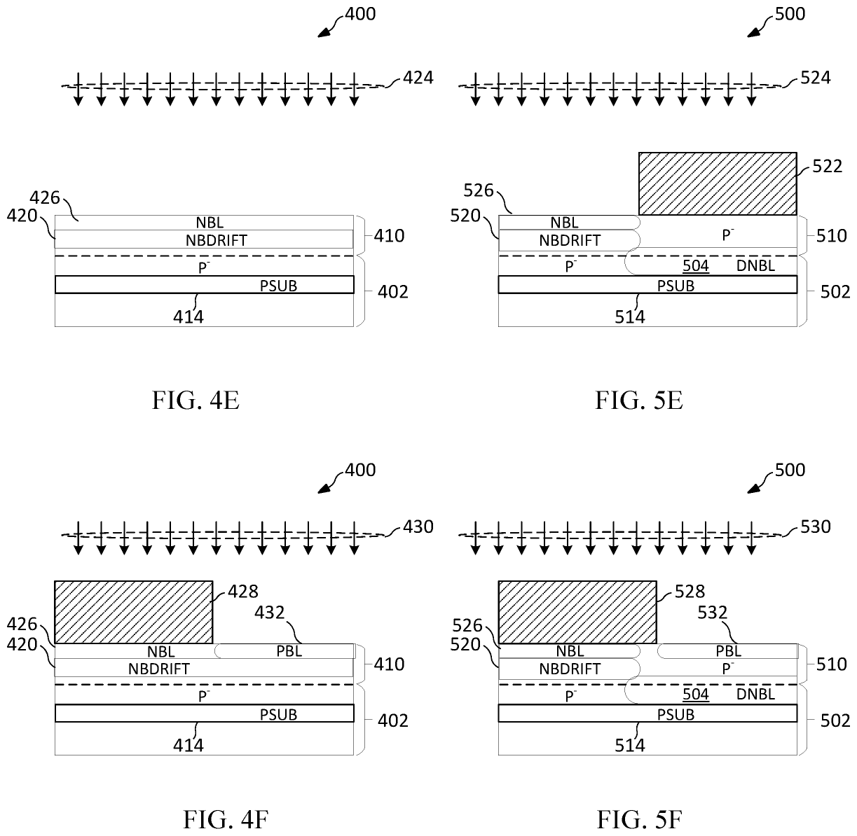

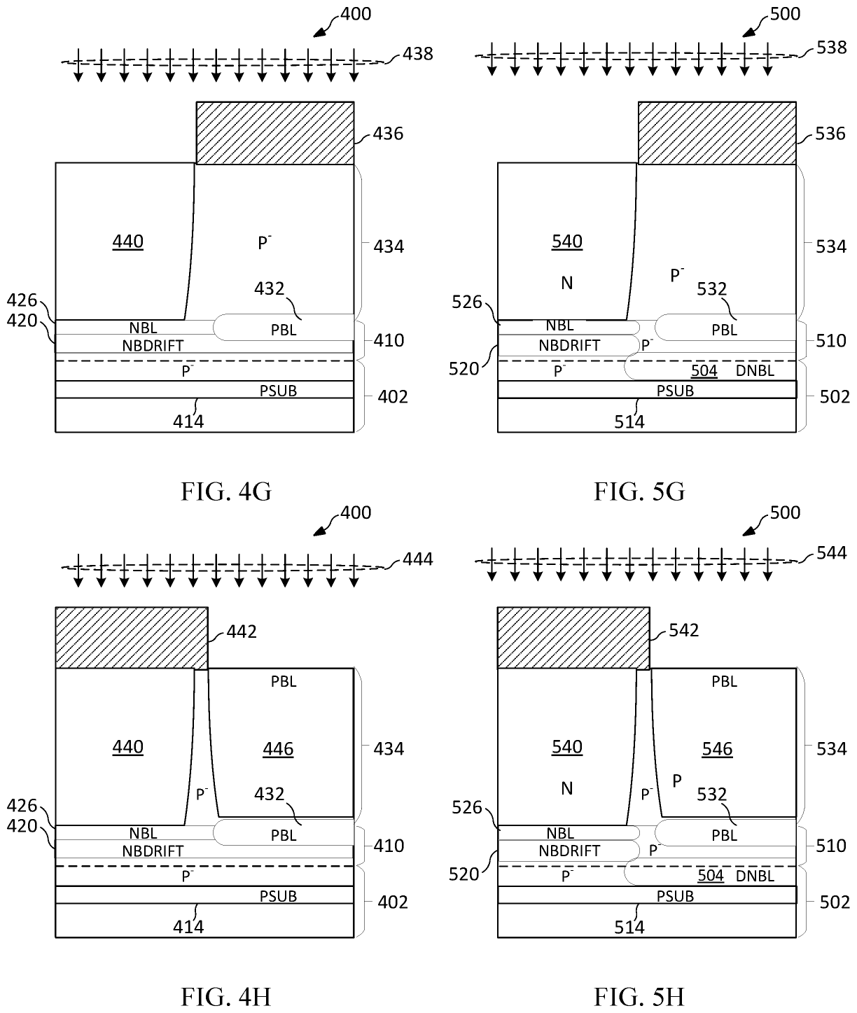

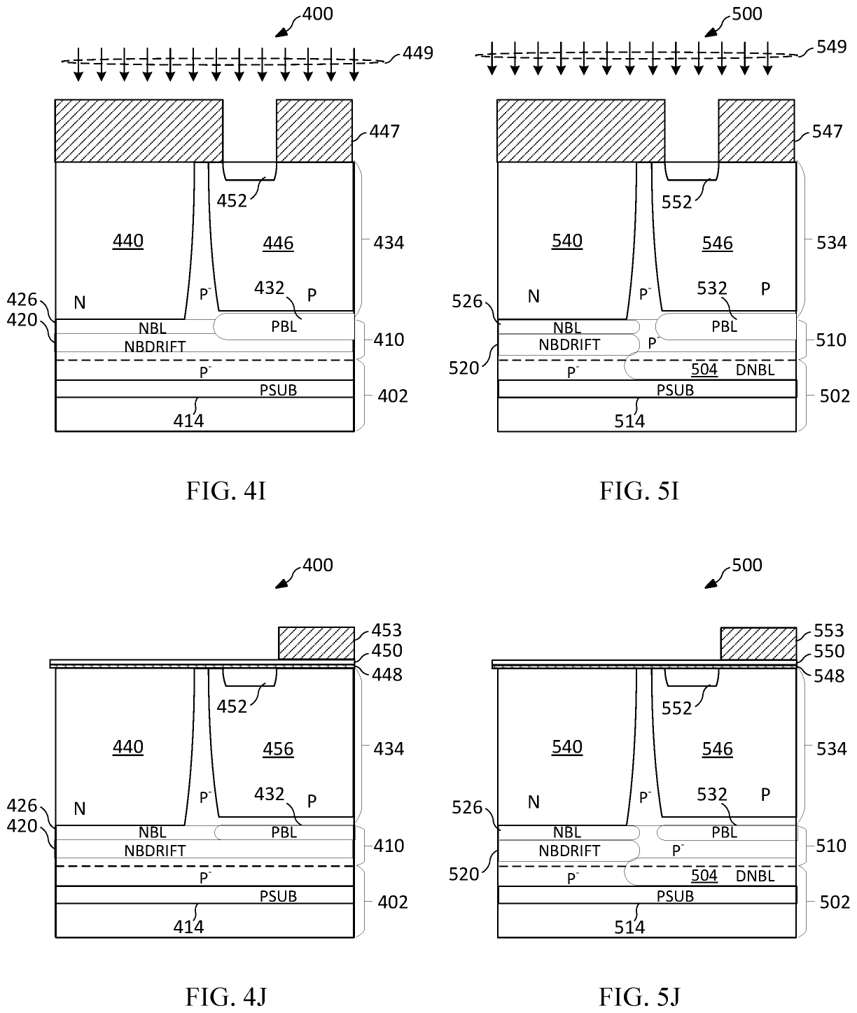

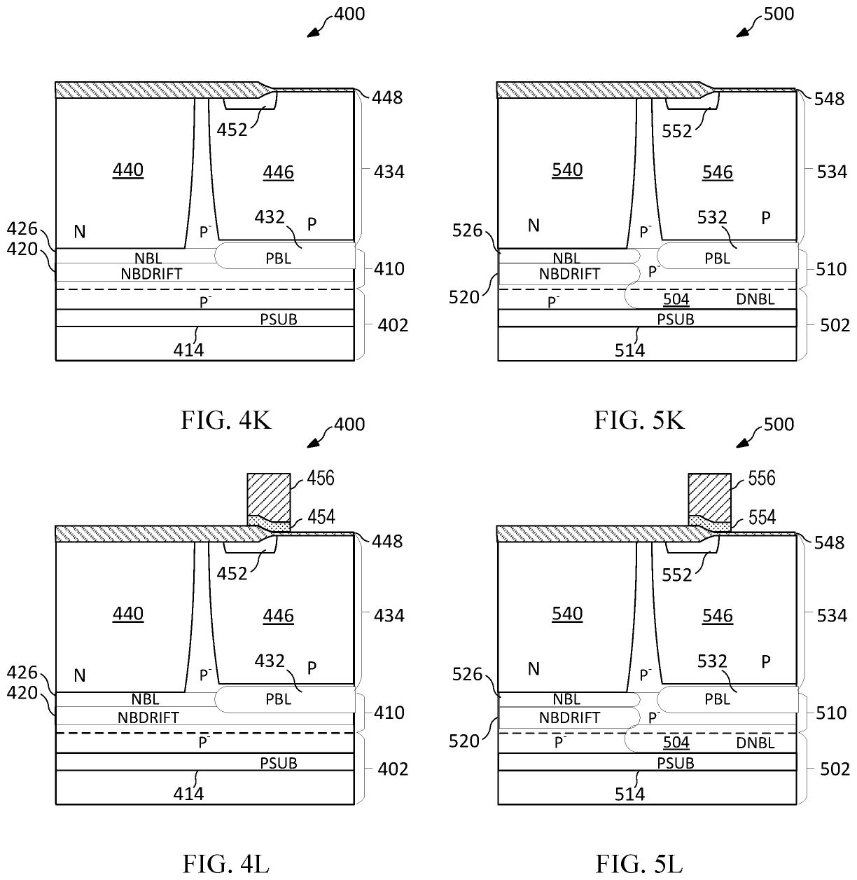

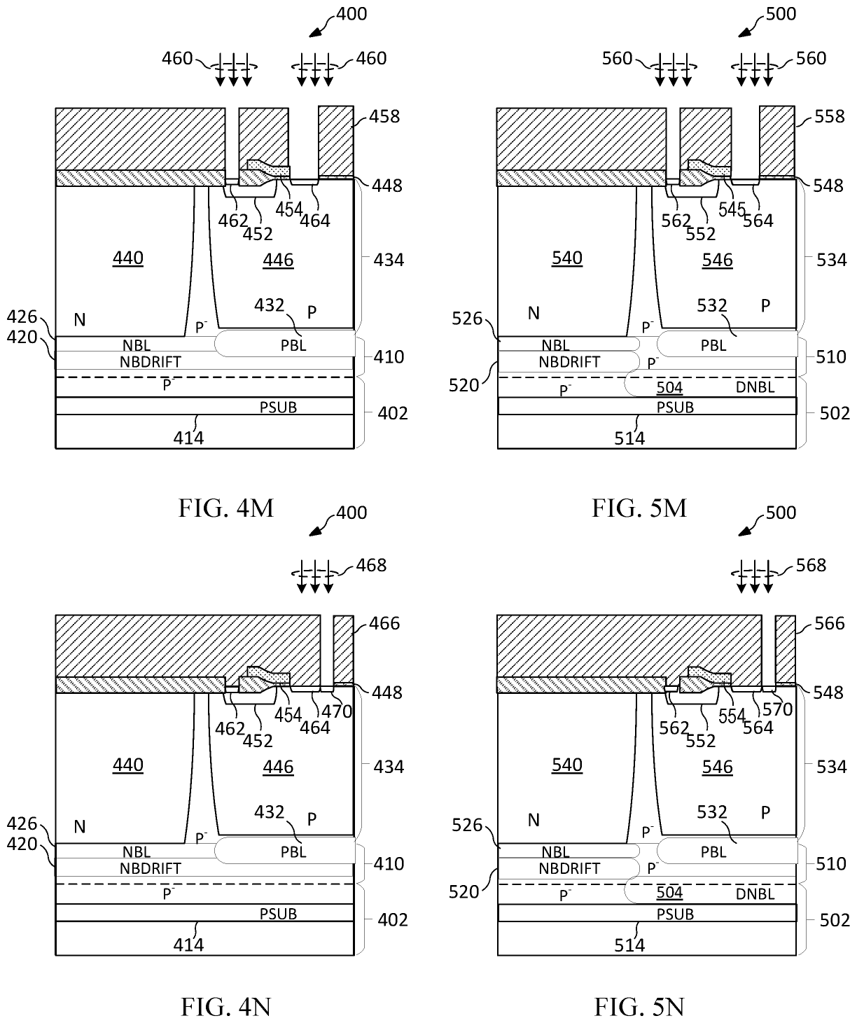

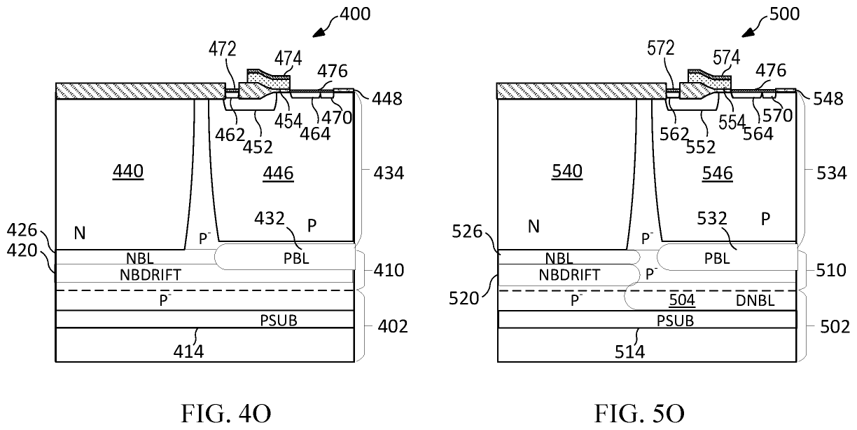

FIG. 3 is a cross-sectional view of an integrated circuit 300 according to various examples of the disclosure. The IC 300 may beneficially increase the breakdown voltage between HB and HS (BViso) relative to baseline implementations. As compared with integrated circuit 200 (FIG. 2), integrated circuit 300 includes a deep N-type buried layer (DNBL) 304 between PBL 332 and PSUB 304. In addition, NBL 326 and NBDRIFT 320 are laterally spaced apart from PBL 332 by a portion of lightly doped P type lower epitaxial layer 310. Further, integrated circuit 300 includes an upper epitaxial layer 334 above the lower epitaxial layer 310. As further described hereinbelow with regard to FIGS. 4 and 5, the additional lower epitaxial layer 310 facilitates formation of DNBL 304 that is conductively coupled to N buried drift layer (NBDRIFT) 320, NBL 326 and N isolation (NISO) region 340, while allowing for spacing SP_{DNBL-PBL} between DNBL 304 and PBL 332 that provides a vertically wider depletion region between these layers in part by virtue of the relatively low doping of the epi layer 310. This spacing thus provides greater breakdown protection between PBL 332 and NBL 326/DNBL 304 while having little or no impact on the performance of other components formed elsewhere on the integrated circuit 300 formed over or into the surface of upper epitaxial layer 334.

With concurrent reference to FIG. 2, substrate 302 is analogous to substrate 202; PSUB region 314 is analogous to PSUB region 214; N isolation region 340 is analogous to N isolation region 240; P well 346 is analogous to P well 246; extended drain 352 is analogous to extended drain 252; contact 362 is analogous to contact 262; drain silicide layer 372 is analogous to drain silicide layer 272; source 364 is analogous to source 264; well contact 370 is analogous to body contact 270; source silicide layer 376 is analogous to source silicide layer 276; gate 354 is analogous to gate 254; silicide layer 374 is analogous to silicide layer 274; and gate oxide layer 348 is analogous to gate oxide layer 248.

The configuration of the integrated circuit 300 of FIG. 3 provides distance between PBL 332 and DNBL 304. In one nonlimiting example, BViso increased from about 20 V to about 40 V for SP_{NBL-PBL} equal to about 2 μm. This configuration had no more than a negligible impact on LDMOS transistors configured to have a source-to-drain breakdown voltage (BVdss) of 30, 200, and 700 volts, respectively. While the increased breakdown voltage may be beneficial in some implementations, it may be desirable to include devices without some of the features of the integrated circuit 300, e.g., without the DNBL 304 and without the lateral spacing between the NBL 326 and the PBL 332. Thus, various examples in the scope of the disclosure provide a process sequence that can be used to form devices similar to the structural characteristics of the integrated circuit 200 and concurrently form devices consistent with the integrated circuit 300 with no difference in the process sequence used to form both such devices.

FIGS. 4A-4O (collectively “FIGS. 4”) and FIGS. 5A-5O (collectively “FIGS. 5”) provide such sequences of process stages. FIG. 4 are sectional views illustrating an example method of fabricating an example electronic device 400, while FIG. 5 are sectional views illustrating another example method of fabricating another example electronic device 500. In various examples an integrated circuit may include devices exemplified by the electronic device 400 and the electronic device 500 on a same semiconductor substrate.

FIGS. 4A and 5A respectively include a substrate 402 with a top surface 403, and a substrate 502 with a top surface 503. The substrates 402, 502 may be the same substrate, and the devices 400 and 500 may be formed concurrently using same process steps. First photoresist layers 406, 506 are respectively formed over substrates 402 and 502 and used as a mask for ion implantation 408, 508. The substrates 402, 502 may be high-resistivity (lightly doped) P-type substrates with a dopant concentration in a range from about 7.5×10¹³ atoms/cm³ to 1.1×10¹⁴ atoms/cm³. In this example, implantation 408, 508 includes an implantation of N dopant type ions such as antimony (Sb) ions with a density of 2×10¹³ atoms/cm² (with a range of 1×10¹³ atoms/cm² to 4×10¹³ atoms/cm²) and an energy of 60 keV (with a range of 10 keV to 200 keV). After annealing, this implantation produces deep buried N layer (DBNL) 504 extending into the substrate 502. The DBNL layer 504 may have an average dopant concentration in a range from 1×10¹⁶ atoms/cm³ to 1×10¹⁷ atoms/cm³. Optionally the photoresist layer 406 may be omitted and a corresponding DBNL formed within the substrate 402.

In FIGS. 4B and 5B, lower epitaxial (epi) layer 410 is formed over the substrate 402 and lower epi layer 510 is formed over the substrate 502 by epitaxial deposition to a thickness of about 20 nm (with a range of 10 nm to 30 nm). The epi layers 410, 510 may be in situ doped P type with a dopant concentration of about 1×10¹⁵ atoms/cm³.

In the step of FIG. 4C, an implantation 412 of P dopant type ions such as boron (B) ions with a density of 6×10¹¹ atoms/cm² (with a range of 4×10¹¹ atoms/cm² to 1×10¹² atoms/cm²) and an energy of 1.7 MeV (with a range of 1.5 MeV to 2.0 MeV) is implanted into substrate 402 to form PSUB layer 414. In the step of FIG. 5C, an implantation 512 of boron ions with a density of 6×10¹¹ atoms/cm² (with a range of 4×10¹¹ atoms/cm² to 1×10¹² atoms/cm²) and an energy of 1.7 MeV (with a range of 1.5 MeV to 2.0 MeV) is implanted through epi layer 510 into substrate 502 to form PSUB layer 514.

In the step of FIG. 4D, an implantation 418 of N dopant type ions such as phosphorous (P) ions with a density of 2.3×10¹² atoms/cm² (with a range of 1×10¹² atoms/cm² to 4×10¹² atoms/cm²) and an energy of 60 keV (with a range of 50 keV to 70 keV) is implanted into substrate 402 to form NBDRIFT layer 420. In the step of FIG. 5D, second photoresist layer 516 is formed and patterned on epi layer 510. An implantation 518 of phosphorous ions with a density of 2.3×10¹² atoms/cm² (with a range of 1×10¹² atoms/cm² to 4×10¹² atoms/cm²) and an energy of 60 keV (with a range of 50 keV to 70 keV) is implanted into epi layer 510 to form NBDRIFT layer 520. Of note, DNBL layer 504 and NBDRIFT layer 520 overlap and thus are in conductive contact with each other.

In the step of FIG. 4E, an implantation 424 of antimony ions with a density of 2×10¹⁵ atoms/cm² (with a range of 1×10¹⁵ atoms/cm² to 3×10¹⁵ atoms/cm²) and an energy of 60 keV (with a range of 50 keV to 70 keV) is implanted into substrate 402 to form NBL layer 426. In the step of FIG. 5E, third photoresist layer 522 is formed and patterned on epi layer 510. An implantation 524 of antimony ions with a density of 2×10¹⁵ atoms/cm² (with a range of 1×10¹⁵ atoms/cm² to 3×10¹⁵ atoms/cm²) and an energy of 60 keV (with a range of 50 keV to 70 keV) is implanted into epi layer 510 to form NBL layer 526. The NBL layers 426, 526 may have an average dopant concentration in a range from 1×10¹⁸ atoms/cm³ to 1×10¹⁹ atoms/cm³. While the DNBL 504 may diffuse toward the top surface 535 and the NBL layer 526 may diffuse toward the substrate 502, a portion of the epi layer 510 may have an unmodified dopant concentration, which in this context means the dopant concertation of this portion remains unchanged from an initial concentration of the epi layer 510 when that layer is formed. Of note, NBL layer 526 and NBDRIFT layer 520 overlap and thus are in conductive contact with each other.

In the step of FIG. 4F, a first photoresist layer 428 is formed and patterned on substrate 402. An implantation 430 of boron ions with a density of 7.25×10¹³ atoms/cm² (with a range of 5×10¹³ atoms/cm² to 9×10¹³ atoms/cm²) and an energy of 60 keV (with a range of 50 keV to 70 keV) is implanted into substrate 402 to form PBL layer 432. In the step of FIG. 5F, fifth photoresist layer 528 is formed and patterned on epi layer 510. An implantation 530 of boron ions with a density of 7.25×10¹³ atoms/cm² (with a range of 5×10¹³ atoms/cm² to 9×10¹³ atoms/cm²) and an energy of 60 keV (with a range of 50 keV to 70 keV) is implanted into epi layer 510 to form PBL layer 532.

In the step of FIG. 4G, first upper epi layer 434 is formed to a thickness of 1μ (with a range of 0.8μ to 1.4μ) by epitaxial deposition. A sixth photoresist layer 436 is formed and patterned on epi layer 434. Sixth photoresistor layer 436 serves as a mask for an implantation 438 of phosphorous ions with a density of 4×10¹² atoms/cm² (with a range of 2×10¹² atoms/cm² to 7×10¹² atoms/cm²) and an energy of 80 keV (with a range of 70 keV to 90 keV) to form isolation region 440. In addition to serving as isolation, isolation region 440 may also serve as a well for other devices, such as a p-channel transistor (not shown). In the step of FIG. 5G, second upper epi layer 534 is formed to a thickness of 1 μm (with a range of 0.8 μm to 1.4 μm) by epitaxial deposition. A seventh photoresist layer 536 is formed and patterned on epi layer 534. Seventh photoresistor layer 536 serves as a mask for an implantation 538 of phosphorous ions with a density of 4×10¹² atoms/cm² (with a range of 2×10¹² atoms/cm² to 7×10¹² atoms/cm²) and an energy of 80 keV (with a range of 70 keV to 90 keV) to form isolation region 540. In addition to serving as isolation, isolation region 540 may also serve as a well for other devices, such as a p-channel transistor (not shown).

In the step of FIG. 4H, an eighth photoresist layer 442 is formed and patterned on epi layer 434. An implantation 444 of boron ions with a density of 4×10¹² atoms/cm² (with a range of 2×10¹² atoms/cm² to 7×10¹² atoms/cm²) and an energy of 80 keV (with a range of 70 keV to 90 keV) is implanted into epi layer 434 to form P well 446. In the step of FIG. 5H, ninth photoresist layer 542 is formed and patterned on epi layer 534. An implantation 544 of boron ions with a density of 4×10¹² atoms/cm² (with a range of 2×10¹² atoms/cm² to 7×10¹² atoms/cm²) and an energy of 80 keV (with a range of 70 keV to 90 keV) is implanted into epi layer 534 to form P well 546.

In the step of FIG. 4I, a tenth photoresist layer 447 is formed and patterned on epi layer 434. An implantation 449 of phosphorous ions with a density of 1×10¹⁵ atoms/cm² (with a range of 0.5×10¹⁵ atoms/cm² to 2×10¹⁵ atoms/cm²) and an energy of 35 keV (with a range of 30 keV to 40 keV) is implanted into epi layer 434 to form drain 452. In the step of FIG. 5I, eleventh photoresist layer 547 is formed and patterned on epi layer 534. An implantation 549 of phosphorous ions with a density of 1×10¹⁵ atoms/cm² (with a range of 5×10¹⁴ atoms/cm² to 2×10¹⁵ atoms/cm²) and an energy of 35 keV (with a range of 30 keV to 40 keV) is implanted into epi layer 534 to form drain 552.

In the step of FIG. 4J, a gate oxide layer 448 having a thickness of approximately 40 nm using thermal oxidation in a steam ambient followed by a silicon nitride layer 450 that is deposited using chemical vapor deposition to a thickness of approximately 140 nm is formed on epi layer 434. A twelfth photoresist layer 453 is formed and patterned on silicon nitride layer 450. Twelfth photoresist layer 453 is used to pattern silicon nitride layer using plasma etching, for example. Twelfth photoresist layer 453 is then removed. In some examples a local oxidation of silicon (LOCOS) process may be used to locally thicken exposed portions of gate oxide layer 448 as shown. Such examples may use steam oxidation at a temperature of 900° C. to locally increase the thickness of the gate oxide layer 448 to approximately 100 nm, for example, as shown in FIG. 4K. Similarly, in the step of FIG. 5J, a gate oxide layer 548 is formed to a thickness of approximately 40 nm by thermal oxidation followed by forming a silicon nitride layer 550 using CVD to a thickness of approximately 140 nm on epi layer 534. A thirteenth photoresist layer 553 is formed and patterned on silicon nitride layer 550. Thirteenth photoresist layer 553 is used to pattern silicon nitride layer using plasma etching, for example. Thirteenth photoresist layer 553 is then removed. As for the gate oxide layer 448, exposed portions of the gate oxide 548 may be thickened to about 100 nm by steam oxidation as shown in FIG. 5K. In either example, shallow trench isolation (STI) may be used in lieu of LOCOS.

In the step of FIG. 4L, a polysilicon layer (not shown) is deposited on gate oxide layer 448 to a thickness of approximately 150 nm using chemical vapor deposition (CVD), for example. A fourteenth photoresist layer 456 is formed and patterned on the polysilicon layer. The fourteenth photoresist layer 456 is used as a mask to etch the polysilicon layer using plasma etching, for example, to form gate 454. The fourteenth photoresist layer 456 is then removed. In the step of FIG. 5L, a polysilicon layer (not shown) is deposited on gate oxide layer 548 to a thickness of approximately 150 nm using chemical vapor deposition (CVD), for example. A fifteenth photoresist layer 556 is formed and patterned on the polysilicon layer. The photoresist layer 556 is used as a mask to etch the polysilicon layer using plasma etching, for example, to form gate 554. The photoresist layer 556 is then removed.

In the step of FIG. 4M, a sixteenth photoresist layer 458 is formed and patterned on gate oxide layer 448 and gate 454. Plasma etching, for example, removes gate oxide layer 448 where exposed by sixteenth photoresist layer 458 and gate 454 using plasma etching, for example. An implantation 460 of phosphorous ions with a density of 1×10¹⁶ atoms/cm² (with a range of 0.5×10¹⁶ atoms/cm² to 2×10¹⁶ atoms/cm²) and an energy of 20 keV (with a range of 15 keV to 25 keV) is implanted into epi layer 434 to form drain contact 462 and source 464. In the step of FIG. 5M, seventeenth photoresist layer 558 is formed and patterned on gate oxide layer 548 and gate 554. Plasma etching, for example, removes the portions of gate oxide layer 548 exposed by seventeenth photoresist layer 558 and gate 554. An implantation 560 of phosphorous ions with a density of 1×10¹⁶ atoms/cm² (with a range of 5×10¹⁵ atoms/cm² to 2×10¹⁶ atoms/cm²) and an energy of 20 keV (with a range of 15 keV to 25 keV) is implanted into epi layer 534 to form drain contact 562 and source 564.

In the step of FIG. 4N, an eighteenth photoresist layer 466 is formed and patterned on gate oxide layer 448, gate 454, and the exposed portions of epi layer 434. Plasma etching, for example, removes gate oxide layer 448 where exposed by eighteenth photoresist layer 466 using plasma etching, for example. An implantation 468 of boron ions with a density of 1×10¹⁶ atoms/cm² (with a range of 0.5×10¹⁶ atoms/cm² to 2×10¹⁶ atoms/cm²) and an energy of 20 keV (with a range of 15 keV to 25 keV) is implanted into epi layer 434 to form body contact 470. In the step of FIG. 5M, nineteenth photoresist layer 566 is formed and patterned on gate oxide layer 548, gate 554, and the exposed portions of epi layer 534. Plasma etching, for example, removes the portions of gate oxide layer 548 exposed by nineteenth photoresist layer 566. An implantation 568 of boron ions with a density of 1×10¹⁶ atoms/cm² (with a range of 5×10¹⁵ atoms/cm² to 2×10¹⁶ atoms/cm²) and an energy of 20 keV (with a range of 15 keV to 25 keV) is implanted into epi layer 534 to form body contact 570.

In the step of 4O, a layer of metal not shown, such as titanium, tungsten, or cobalt, is deposited overall using sputtering, for example. Annealing causes the portions of gate 454 and epi layer 434 to convert to a silicide. Thus, drain contact silicide layer 472 forms on drain contact 462; gate silicide layer 474 forms on gate 454; and source silicide layer 476 forms on source 464 and body contact 470. Thus, source 464 is strapped to P well 446 to provide a source strapped configuration in this example.

In the step of 5O, a layer of metal not shown, such as titanium, tungsten, or cobalt, is deposited overall using sputtering, for example. Annealing causes the portions of gate 554 and epi layer 534 to convert to a silicide. Thus, drain contact silicide layer 572 forms on drain contact 562; gate silicide layer 574 forms on gate 554; and source silicide layer 576 forms on source 564 and body contact 570. Thus, source 564 is strapped to P well 546 to provide a source strapped configuration in this example. Of note, the process of FIG. 5 provides nearly double BViso while having minimal impact on BVdss while only requiring two additional masks and two additional processing steps.

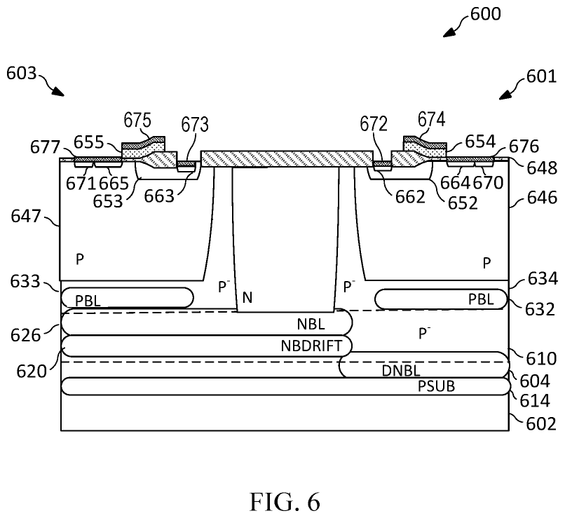

FIG. 6 is a cross-sectional view of an example integrated circuit 600 including a high BViso transistor 601 and a low BViso transistor 603. The transistors are examples of active devices, which may be LDMOS transistors or other type of transistors. Integrated circuit 600 may be fabricated using the steps illustrated in FIGS. 4 and 5. Lower epitaxial layer 610 and upper epitaxial layer 634 are formed on substrate 602 like epi layer 510 and epi layer 534, respectively. PSUB 614 is implanted under both transistor 601 and transistor 603. DNBL 604 is only implanted under transistor 601. NBDRIFT 620 and NBL 626 extend under transistor 603, but not under transistor 601. PBL 632 and PBL 633 are implanted at the same time under transistor 601 and transistor 603, respectively. N isolation region 640 is formed between transistor 601 and transistor 603. Gate oxide layers 648 and 649 are respectively formed in transistors 601 and 603 using the steps described in FIGS. 4 and 5, and a thick oxide layer 650 is formed between the transistors 601 and 603 as previously described. P well 646, drain 652, drain contact 662, gate 654, source 664, body well contact 670, source silicide layer 676, gate silicide layer 674, and drain contact silicide layer 672, are formed using the same steps as P well 647, drain 653, drain contact 663, gate 655, source 665, body contact 671, source silicide layer 677, gate silicide layer 675, and drain contact silicide layer 673, respectively. The steps for making these components are illustrated in FIG. 5 in making P well 546, drain 552, drain contact 562, gate 554, source 564, body contact 570, source silicide layer 576, gate silicide layer 574, and drain contact silicide layer 572, respectively. Thus, high BViso transistor 601 and low BViso transistor 603 are fabricated concurrently in the same substrate using a same sequence of processing steps.

Modifications are possible in the described examples, and other examples are possible, within the scope of the claims.

What is claimed is:

1. An integrated circuit comprising:
a first epitaxial layer having a first conductivity type over a semiconductor substrate having a top surface;
a second epitaxial layer having a first conductivity type over the first epitaxial layer;
a first doped region having a different second conductivity type between and extending into the substrate and the first epitaxial layer;
a second doped region having the second conductivity type between and extending into the first epitaxial layer and the second epitaxial layer;
a well region having the first conductivity type extending from the top surface into the second epitaxial layer over the first doped region; and
an active device formed over the first doped region in the well.

2. The integrated circuit of claim 1, wherein the second doped region has a higher average dopant concentration than does the first doped region.

3. The integrated circuit of claim 1, wherein a portion of the first epitaxial layer between the first and second doped regions has an unmodified dopant concentration.

4. The integrated circuit of claim 1, wherein the first doped region merges with a third doped region having the second conductivity type that is laterally spaced apart from the first doped region and vertically spaced apart from the substrate.

5. The integrated circuit of claim 4, wherein a portion of the first epitaxial layer between the third doped region and the substrate has an unmodified dopant concentration.

6. The integrated circuit of claim 4, further comprising a fourth doped region having the second conductivity type and located between the third doped region and the substrate surface, and a portion of the first epitaxial layer between the second doped region and the fourth doped region has an unmodified dopant concentration.

7. The integrated circuit of claim 1, wherein the active device is a transistor.

8. The integrated circuit of claim 1, wherein the active device includes an LDMOS transistor.

9. The integrated circuit of claim 1, wherein the first conductivity type is P-type and the second conductivity type is N-type.

10. An integrated circuit comprising:
a first N-type buried layer extending into a semiconductor substrate;
a first P-type epitaxial layer extending from the first buried layer away from the substrate;
a P-type buried layer extending into the first epitaxial layer over the first N-type buried layer;
a second P-type epitaxial layer extending between the first P-type epitaxial layer and a top surface of the second P-type epitaxial layer;
an unmodified portion of the first P-type epitaxial layer between the first N-type buried layer and the P-type buried layer;
a P-type well in the second P-type epitaxial layer over the P-type buried layer;
a second N-type buried layer extending into the first P-type epitaxial layer and laterally spaced apart from and at a same height over the substrate as the P-type layer;
a third N-type buried layer in the first epitaxial layer between the second N-type layer and the substrate; and
a transistor formed in the P-type well.

11. The integrated circuit of claim 10, wherein the transistor is an LDMOS transistor.

12. The integrated circuit of claim 10, wherein the first N-type buried layer is approximately laterally coextensive with the P-type well.

13. The integrated circuit of claim 10, wherein a portion of the first P-type epitaxial layer having unmodified dopant concentration is located between the P-type buried layer and the first N-type buried layer.

14. The integrated circuit of claim 13, wherein a portion of the first P-type epitaxial layer having unmodified dopant concentration is located between the P-type buried layer and the second N-type buried layer.

15. A method comprising:
implanting a first dopant type into a substrate to form a first doped region in the substrate having a first conductivity type;
forming a first epitaxial layer on the substrate, wherein the first doped region extends into the first epitaxial layer during formation of the first epitaxial layer;
forming a second epitaxial layer on the first epitaxial layer;
implanting the first dopant type to form a second doped region in the first epitaxial layer and the second epitaxial layer having the first conductivity type;
implanting a second dopant type into the second epitaxial layer to form a well in the second epitaxial layer having a second conductivity type; and
forming an active device formed in the well.

16. The method of claim 15, wherein the well is a first well and the active device is a first active device, and further comprising:
forming a second well concurrently with the implanting a second dopant type into the second epitaxial layer to form the first well, wherein the second doped region extends under the second well; and
forming a second active device in the second well.

17. The method of claim 15, wherein the first doped region is approximately coextensive with the well in a direction parallel to a surface of the second epitaxial layer.

18. The method of claim 15, wherein the second doped region does not extend to an area approximately coextensive with the well in a direction parallel to a surface of the second epitaxial layer.

19. The method of claim 15, further including implanting the second dopant type to form a first buried layer having the second conductivity type between the first doped region and the well, wherein the first buried layer is approximately coextensive with the well in a direction parallel to a surface of the second epitaxial layer.

20. The method of claim 15, further including implanting the first dopant type to form a drift region having the first conductivity type, the drift region in contact with the first doped region and the second doped region.
